(19) United States
(12) Patent Application Publication
(10) Pub. No.: US 2025/0255194 A1
(43) Pub. Date: Aug. 7, 2025

(54) GIANT SPIN HALL EFFECT AND SPIN-ORBIT TORQUES IN 5D TRANSITION METAL - ALUMINUM ALLOYS FROM EXTRINSIC SCATTERING

(71) Applicant: MAX PLANCK GESELLSCHAFT ZUR FÖRDERUNG DER WISSENSCHAFTEN EV, München (DE)

(72) Inventors: Stewart S.P. PARKIN, Halle (DE); Peng WANG, Halle (DE)

(73) Assignee: MAX PLANCK GESELLSCHAFT ZUR FÖRDERUNG DER WISSENSCHAFTEN EV, München (DE)

(21) Appl. No.: 18/856,918

(22) PCT Filed: Apr. 5, 2023
(86) PCT No.: PCT/EP2023/058939

§ 371 Date: Oct. 15, 2024

(30) Foreign Application Priority Data
Apr. 19, 2022 (EP) 22168803.9

(51) Int. Cl. H10N 50/85; C22C 21/00; C23C 14/18; C23C 14/34; C23C 14/35; G11C 11/16; G11C 19/08; H10N 50/01; H10N 50/10; H10N 50/20

(52) U.S. Cl. CPC H10N 50/85; C23C 14/185; C23C 14/3414; C23C 14/35; G11C 11/161; G11C 19/0841; H10N 50/01; H10N 50/10; H10N 50/20; C22C 21/00

(57) ABSTRACT

The present invention relates to a Giant spin Hall effect material based on MₓAl₁₀₀₋ₓ, in which M=5d metal (Lu, Hf, Ta, W, Re, Os, Ir, Pt [=5d¹-5d⁹], and x=15-40. Furthermore, the present invention concerns a method of making such Giant spin Hall effect material and a racetrack memory incorporating the Giant spin Hall effect material.

The generation of spin currents from charge currents via the spin Hall effect is both of fundamental and technological interest. Here we show some of the largest spin Hall effects yet observed via extrinsic scattering in a large class of binary compounds formed from a 5d element and aluminum with a giant spin Hall angle of ˜1 in the compound Os₂₂Al₇₈. We find a critical composition of the 5d element where there is a structural phase boundary between poorly and highly textured crystalline material, where the spin Hall angle takes a maximum value. Furthermore, we find a systematic increase in the spin Hall conductivity and the spin Hall angle at this critical composition as the atomic number of the 5d element is systematically increased. This clearly shows that the spin Hall effect and spin Hall conductivity are derived from extrinsic scattering mechanisms related to the potential mismatch between the 5d element and Al. These studies show the importance of extrinsic mechanisms derived from potential mismatch as a route to obtaining large spin Hall angles with high technological impact. Indeed, we demonstrate that a state-of-the-art racetrack device has a several-fold increased current induced domain wall efficiency using these materials as compared to prior-art materials.

### INTRODUCTION

Spintronics is driven by the generation of spin currents and especially their use as spin torques in manipulating magnetization.^{[1-5]} This is the principal mechanism for writing magnetic memory bits in magnetic random-access memories (MRAMs)^{[6]} and in moving magnetic bits, namely domain walls (DW) in magnetic racetrack memories.^{[7, 8]} Spin currents can be generated from charge currents via the spin Hall effect (SHE). There has been much interest in certain classes of high-quality, crystalline compounds that could give rise to large spin Hall effects (SHEs) that originate from the intrinsic electronic band structures of such materials^{[9, 10]}: such materials include topological insulators,^{[11-13]} and Dirac and Weyl semimetals.^{[14-16]}

Current induced motion of domain walls (DW) in synthetic antiferromagnetic (SAF) racetrack layers has been shown to display high current induced domain wall velocities.^{[31]} Yet, the domain wall velocity still needs to be improved, ideally at simultaneously reduced threshold current density above which the DW starts to move.

Here we show very large SHEs arising rather from extrinsic scattering in highly resistive alloys formed from a 5d element and aluminum at room temperature that are highly useful for practical applications.

The spin-orbit interaction (SOI) plays a central role in the SHE such that, typically, the larger the atomic number Z, the larger is the SHE. Furthermore, the bigger the contrast between Z of the constituent elements in a compound or alloy, the larger will be the extrinsic scattering and, consequently, the SHE.^{[17, 18]} In this regard, alloying light metals such as aluminum with a 5d transition metal has the potential to generate a large extrinsic SHE.^{[19]} Here we show that MₓAl₁₀₀₋ₓ (M=Ta, W, Re, Os, Ir, and Pt; x=15-40) alloys exhibit dramatic changes in not only the resistivity ρ but also the spin Hall angle (SHA) θ_{SH} and spin Hall conductivity (SHC) σ_{SH} as a function of their composition, x. We find that there is, in many cases, a transition from a highly disordered, near amorphous phase, to a highly crystalline phase at a critical composition. Furthermore, we find that the resistivity and spin Hall angle exhibit the largest values near the amorphous-crystalline boundary in which extrinsic scattering is maximized. To support this conjecture, we find that the magnitude of the maximum resistivity and the corresponding SHA vary systematically with Z. This shows that the filling of the 5d plays a critical role, such that the resistivity and SHA are related to the number of unpaired electrons in the 5d shell of M, so that ρ exhibits a maximum value for M=Re or Os (number of unpaired d electrons due to Hund's rule=5, 6, respectively). We find that the resistivity is approximately linearly proportional to the spin Hall angle, so that the power consumption (˜ρ/θ_{SH}²) that varies inversely with θ_{SH} is minimized for maximum SHA.^{[20]} Hence, we find that MₓAl₁₀₀₋ₓ are excellent sources of spin-orbit torque sources with smaller power consumptions, compared to established spin Hall metallic elements. On the other hand, we find that when the 5d shell is fully filled, i.e. M=Au, no significant changes in ρ and θ_{SH} as a function of x are found, thereby confirming that the unpaired orbitals in 5d shell plays a key role in the formation of scattering potentials for ρ and the extrinsic SHE.

### Results and Discussion

Crystal Structure and Resistivity of MₓAl₁₀₀₋ₓ Alloys

The MₓAl₁₀₀₋ₓ films used in this study were prepared using dc magnetron co-sputtering from a 5d metal M target and an Al sputter target to deposit MₓAl₁₀₀₋ₓ films on top of a [001]-oriented MgO substrate in an ultra-high vacuum chamber. The composition was varied for x varying from ˜10 to ˜90 atomic % by varying the power applied to each of the targets. Typical deposition rates were 0.5-2 Å/s and the films were deposited at room temperature. On top of these films were grown magnetic layers to form magnetic racetracks or to form structures suitable for spin-torque ferromagnetic resonance (ST-FMR) studies. The structures were protected from oxidation by a 4 nm thick MgO layer capping layer (see Methods for details). The sheet resistances R_{S} of the as-grown films are measured by a four-point in-line probe method, from which ρ is obtained from the relationship ρ=Rₛt, where t is the film thickness. The crystal structures of the films were investigated by x-ray diffraction (XRD) and cross-section transmission electron microscopy (XTEM).

The XRD experiments were carried out with a four-circle diffractometer using Cu-K-α1 radiation and employing a two-dimensional pixel detector. The data shown in FIG. S1 were collected in the symmetric θ-2θ scan mode corresponding to longitudinal scans along the [001] direction in reciprocal space. The structure of all the alloys, with the exception of Ta—Al, was found to vary systematically with x, from a poorly crystalline, nearly amorphous structure for small x to a highly textured, crystalline structure for x larger than a critical value, x_{crit}˜20-40 atom %, that depends on M. As M is varied systematically along the 5d period we find a systematic trend to form a well-ordered crystalline phase with increasing number of 5d electrons. For the early elements, Ta and Re, only poorly ordered phases are observed almost independent of x (see FIG. S1a and c), while for W we find only the (002) reflection of the bulk-like, completely chemically, disordered phase with space group (SGR) symmetry Im3̅m in the region between x=53 and 93 atom %. By contrast, the late d-transition elements (Os, Ir, Pt and Au) form increasingly well-ordered structures of the CsCl type (SGR symmetry Pm3̅m, often labelled L1₀), as shown in FIG. 1a. For instance, a detailed analysis of the IrₓAl₁₀₀₋ₓ alloys with intermediate values of x indicates almost perfect ordering of the elements on the distinct lattice sites (000) and (½ ½ ½), where only about 10-15 atom % of Ir (Al) are exchanged with the Al (Ir) sites (for more details see SI).

In all cases where a crystalline CsCl-type structure is formed at intermediate values of x, a resistivity maximum is observed at the onset of the long-range order, which is identified at x lying in the range of about x=20-40 atom %, depending on M (see FIG. 1b, c). This concentration likely corresponds to a “percolation limit” where the metal number density exceeds a critical value where the average M-M distance and interaction becomes large enough to establish a long-range ordered structure.^{[21, 22]} This coincides with the resistivity maximum as the crystalline domains are still small and the number of grain boundaries is large. The maximum value of ρ˜1100 μΩ cm is observed for Os₂₂Al₇₈. The peak values of the resistivity are considerably higher than the end members in each M-Al case (˜3 μΩ cm for Al and Au and 5 to 20 μΩ cm for the other M).

Beyond this critical concentration the resistivity decreases as the size of the coherently scattering domains and the degree of chemical ordering increases. The latter is directly evidenced by the narrowing of the x-ray reflections (see e.g. FIG. S1e for x=50 atom % and FIG. S1g for x=41 atom %). Structural ordering can be estimated by the ratio between the intensities of the (001) and the (002) reflections which has a maximum (i.e. maximum ordering within the CsCl-type structure) for x (atom %) in the range (33<x<58) for IrₓAl₁₀₀₋ₓ as well as for PtₓAl₁₀₀₋ₓ in the range 32<x<50. Finally in the high-x limit we observe for the IrₓAl₁₀₀₋ₓ another phase transition to a Fm3̅m symmetry Ir metal phase (see FIG. S1f), in which the Al atoms can be viewed as diluted within the Ir matrix.

The c lattice parameter systematically increases with increasing x within the crystalline phase region, as shown in FIG. 1d. For example, for IrₓAl₁₀₀₋ₓ, c increases by ˜10% as x is increased from 33 to 61 atom %, consistent with an enhanced tetragonality. For x=50 atom % cross-sectional transmission electron microscopy shows a highly ordered crystalline phase consistent with the L1₀ structure, as shown for Ir₅₀Al₅₀ in FIG. 1e.

### Evaluation of Spin Hall Angle

The charge-to-spin conversion efficiency, i.e. the spin Hall angle θ_{SH} of the MₓAl₁₀₀₋ₓ materials are measured in patterned device structures formed from MₓAl₁₀₀₋ₓ (43 Å)|Co₂₀Fe₆₀B₂₀ (CFB) (60 Å) using a ferromagnetic layer of CFB and a spin-torque ferromagnetic resonance (ST-FMR) technique (FIG. 2a) at ambient temperature by analyzing FMR line widths as a function of DC bias current^{[23]} (see SI for details). Note that the measured θ_{SH} corresponds to an effective θ_{SH} that includes the interface transparency^{[24]} between M-Al and the CFB ferromagnetic layer that will result in a reduction in the spin current that can cross this interface (and, therefore, the extracted SHA) (see FIG. S3-S9). A very important finding is that, as shown in FIG. 2b, θ_{SH} increases systematically with the resistivity in the poorly crystalline phase of the MₓAl₁₀₀₋ₓ films. The maximum value of θ_{SH}˜1.04 is found in Os—Al at the composition that displays the largest value of ρ. As for the highly textured L1₀ phase in both OsₓAl₁₀₀₋ₓ and IrₓAl₁₀₀₋ₓ, θ_{SH} also increases with their resistivity, just as in the amorphous phase, while θ_{SH} for PtₓAl₁₀₀₋ₓ decreases slightly as ρ increases, as shown in FIG. 2c. The values of θ_{SH} are very large and considerably larger than those that have been reported for the pure elements Pt^{[23]}, Ta^{[25]} or W^{[26]}, and also oxidized W that displays perhaps the largest value of θ_{SH} yet reported (˜−0.5).^{[27]}

The values of the effective θ_{SH} found for the member of each MₓAl₁₀₀₋ₓ series of compounds with the maximum resistivity are plotted in FIG. 2d versus the atomic number Z. For both M=Os and Ir, values of θ_{SH} significantly close or larger than 1 are found. Interestingly, ρ displays a similar dependence on Z as does θ_{SH}. These data clearly show that the filling of the 5d-shell plays a key role in the electrical conductivity and charge-to-spin conversion. Note that the power consumption in spin torque processes has been shown to vary as ρ/θ_{SH}².^{[20]} This quantity is plotted versus Z in FIG. 2e, showing that the power consumption is minimized near the atomic number at which ρ and θ_{SH} are maximized. Finally, the spin Hall conductivity σ_{SH}θ_{SH}×σₓₓ, which is plotted in FIG. 2f versus Z, increases monotonically with Z reaching a maximum and very high value of 2.34±0.61 (10⁵ ℏ/2e Ω⁻¹ m⁻¹) in Pt₄₁Al₅₉ (FIG. 2f), which is comparable with the previously reported value 2.0 (10⁵ ℏ/2e Ω⁻¹ m⁻¹) from Pt₈₀Al₂₀.^{[28]}

### Current Induced Domain Wall Motion in IrAl-SAFs

As mentioned earlier, the SHE finds a very important application in the manipulation of magnetization via spin torques derived from spin currents.^{[29, 30]} We have applied our finding of giant SHEs in MₓAl₁₀₀₋ₓ films to the current induced motion of domain walls in synthetic antiferromagnetic (SAF) racetrack layers, that have been shown to display the highest current induced domain wall velocities.^{[31]} We consider the case of several Ir—Al alloys as the source of the spin current and we form SAF racetracks from Co/Ni/Co trilayer structures grown on top of the L1₀-ordered IrAl alloy layer. Interestingly, we find that the Co and Ni layers grow oriented [001] with excellent lattice matching (see SI FIG. S14). This is distinct from typical cases in which Co and Ni layers are oriented along [111] when grown on Pt or Ir layers. Furthermore, we find that the Ir-Al|Co|Ni|Co stacks display excellent perpendicular magnetic anisotropy and a large anomalous Hall resistance (R_{H}˜4Ω) (see SI FIG. S14). Finally, note that we use RuAl as an antiferromagnetic coupling spacer layer instead of Ru since RuAl also forms an L1₀-structure on [001]-oriented MgO substrates (see SI FIG. S15). The complete film stack of IrₓAl₁₀₀₋ₓ 3 Co|7 Ni|2.5 Co|8 RuAl 13 Co|7 Ni 13 Co (thickness in A) shows an [001] orientation throughout the whole stack (see SI FIG. S16a). The hysteresis loops of these stacks exhibit out-of-plane magnetized spin-flop transitions, thereby showing that the RuAl spacer layer induces a strong antiferromagnetic exchange coupling between the two Co/Ni/Co ferromagnetic layers (FIG. 3b). The ratio of the remanent (M_{R}) to saturation magnetization (Mₛ) is measured to be ˜0.08, close to zero for an ideal SAF structure. The ratio reveals a strong dependence on the IrₓAl₁₀₀₋ₓ composition (see SI FIG. S16) that we suppose is related to a proximity induced moment in the Ir—Al layer.

To investigate the current-induced domain wall motion, μm-wide wires with different lengths and widths are fabricated by photolithography and Ar ion milling (an optical image of a typical device is shown in FIG. 3c). Kerr microscopy is used to monitor the position of individual domain walls after the application of a succession of 5 ns-long current pulses (see Methods for details). The dependence of the DW velocity, v, on the current density, J, is plotted in FIG. 3d for IrₓAl₁₀₀₋ₓ where x is varied from 35 to 58 atom %. Very large DW velocities are found due to a large exchange coupling torque:^{[32]} the largest DW velocity is measured to be ˜650 m s⁻¹ at J˜6×10⁷ A cm⁻² for Ir₄₂Al₅₈. We note that this corresponds to an efficiency that is 3 to 5 times greater than that reported in conventional [111]-textured SAFs based on Co, Ni and Ru layers grown on Pt underlayers. Moreover, the threshold current density, Jₜₕ, above which the DW starts to move is measured to be ˜5×10⁶ A cm⁻² for Ir₃₅Al₆₅ which is considerably lower than previously reported in Ru based SAF structures prepared on Pt layers.^{[31]} The dependence of Jₜₕ and σ_{SH} on Ir content in IrₓAl₁₀₀₋ₓ shows that Jₜₕ decreases with increasing OSH consistent with an increasing spin-orbit torque (FIG. 3e).

The SOT is known to be very sensitive to the detailed structure of the interface between the SOT layer and the magnetic layer.^{[33]} For example, as shown in FIG. 3f, 2 Å thick Ir or Al layers inserted at this interface significantly changes the dependence of v on the current density. The insertion of the Al dusting layer results in a lower terminal value of v˜200 m/s while J_{c} does not change. On the other hand, the insertion of the Ir dusting layer shifts the v-J curve to higher j thus increasing J_{c}. These observations can be accounted for by: (i) a decrease in the DMI by the insertion of an Al dusting layer as compared with the insertion of an Ir dusting layer^{[34]}; (ii) a decrease in the exchange coupling torque^{[31]} due to the increased ratio of M_{R}/M_{S} for the Al insertion layers as compared with the Ir insertion layers, as shown in FIG. S18; (iii) an increase in spin memory loss (δ=t/I_{sf}, t is the thickness of the dusting layer and I_{sf} is the spin diffusion length) arising from the strong spin-orbit interaction of Ir that degrades the strength of the spin-orbit torque as compared with the weaker spin-orbit interaction from Al which displays a very long spin diffusion length^{[35, 36, 37]}. The degradation of the spin-orbit torque leads to an increase of J_{c} for the Ir insertion layers.

### Spin-Orbit Torque Switching of IrAl-SAFs

To further evaluate the SHE from Ir—Al, we carry out SOT-switching experiments using standard Hall bars^{[25]} formed from a synthetic antiferromagnetic (SAF) structure (see the inset of FIG. 4a and SI for the details). The Hall resistance, that is swept along the magnetic easy-axis (out-of-plane), is plotted in FIG. 4b, showing a well-defined spin-flop transition. Current pulses are applied along the Hall bar as an external magnetic field applied along the current direction is switched between ˜±500 Oe (FIG. 4c). The change in Hall resistance equals that for the magnetic field induced switching (FIG. 4b) for the field range from ˜+3 kOe to ˜−3 kOe), thereby showing a complete switching of the SAF layer at J˜+7 MA/cm² which is a smaller critical current density than needed for realistic applications.^{[3]} The flipping of the Hall resistance upon reversal of the in-plane field direction confirms the SOT switching of the magnetic layers.^{[38]} To investigate the reproducibility and reliability of the current induced switching, the switching experiments were repeated more than 10,000 times without any failure, as shown in FIG. 4d-f (see Methods and SI for further details).

### CONCLUSION

Alloys of 5d elements with light elements are shown to give rise to very large spin Hall angles that exceed those of the best known non-topological materials to date. The largest values of ρ and θ_{SH} are observed to be ˜1,000 μΩ cm and 1.04, respectively, in the alloy Os₂₂Al₇₈, while the largest value of σ_{SH} is found to be 2.34 (10⁵ ℏ/2e Ω⁻¹m⁻¹) in Pt₄₁Al₅₉. Moreover, these materials can be prepared by straightforward sputter deposition techniques, rather than molecular beam epitaxy methods, and, furthermore, act as a template for the growth of highly crystalline textured magnetic layers and heterostructures that are the basis of several emerging magnetic non-volatile memory and storage technologies. We demonstrate that using Ir—Al as the source of spin current, highly efficient chiral domain wall motion is found in synthetic antiferromagnetic racetracks with a very low threshold current density. An important finding is that the largest spin Hall angles are found at compositions that lie close to a phase boundary where the structure loses its crystalline texture, and, that the magnitude of the spin Hall angle scales with the resistivity of the 5d-alloy, clearly demonstrating the extrinsic origin of the spin Hall effect. Finally, the power consumption for spin orbit torque switching is minimized for the most resistive alloys. Our findings show that the giant SHE and spin-orbit torques in MₓAl₁₀₀₋ₓ alloys can provide an excellent platform for potential applications in diverse memory and logic devices with highly efficient interconversion of charge-to-spin currents and low power consumption.

### BRIEF DESCRIPTION OF THE FIGURES

FIG. 1. Crystal structure and electronic properties. a) Schematic diagram of the chemically ordered CsCl-type M-Al structure (M=Os, Ir, and Pt). b, c) Sheet resistivity of MₓAl₁₀₀₋ₓ with a poorly crystalline phase (b), and a highly textured crystalline phase (c) as a function of x, respectively. d) Out-of-plane lattice parameter c as a function of x for OsₓAl₁₀₀₋ₓ, IrₓAl₁₀₀₋ₓ and PtₓAl₁₀₀₋ₓ with the L1₀ structure. e) HADDF-STEM image of a 300 Å thick Ir₅₀Al₅₀ thin film.

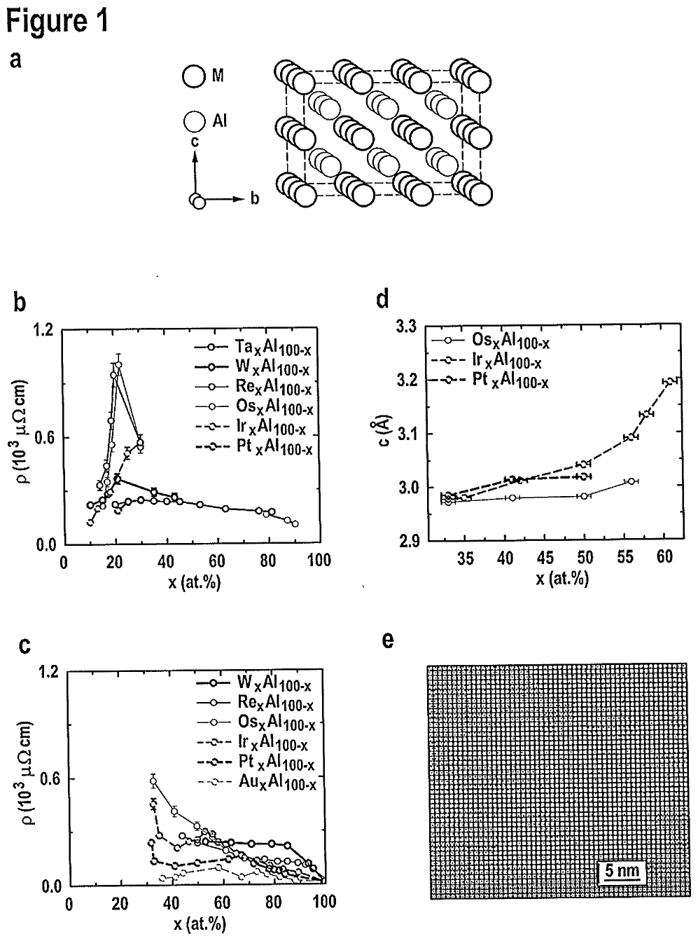

FIG. 2. ST-FMR measurements of MₓAl₁₀₀₋ₓ|Co₂₀Fe₆₀B₂₀ devices. a) Illustration of the ST-FMR experimental setup. b) Effective θ_{SH} as a function of resistivity for several MₓAl₁₀₀₋ₓ compounds which display poor crystallinity. c) Effective θ_{SH} as a function of resistivity for MₓAl₁₀₀₋ₓ with an L1₀ crystalline structure. d) Maximum resistivity and effective θ_{SH} at the same x for MₓAl₁₀₀₋ₓ as a function of atomic number Z. e) The minimum ratio of ρ/θ_{SH}² of MₓAl₁₀₀₋ₓ as a function of Z. f) Maximum spin Hall conductivity σ_{SH} in MₓAl₁₀₀₋ₓ|Co₂₀Fe₆₀B₂₀ samples as a function of Z.

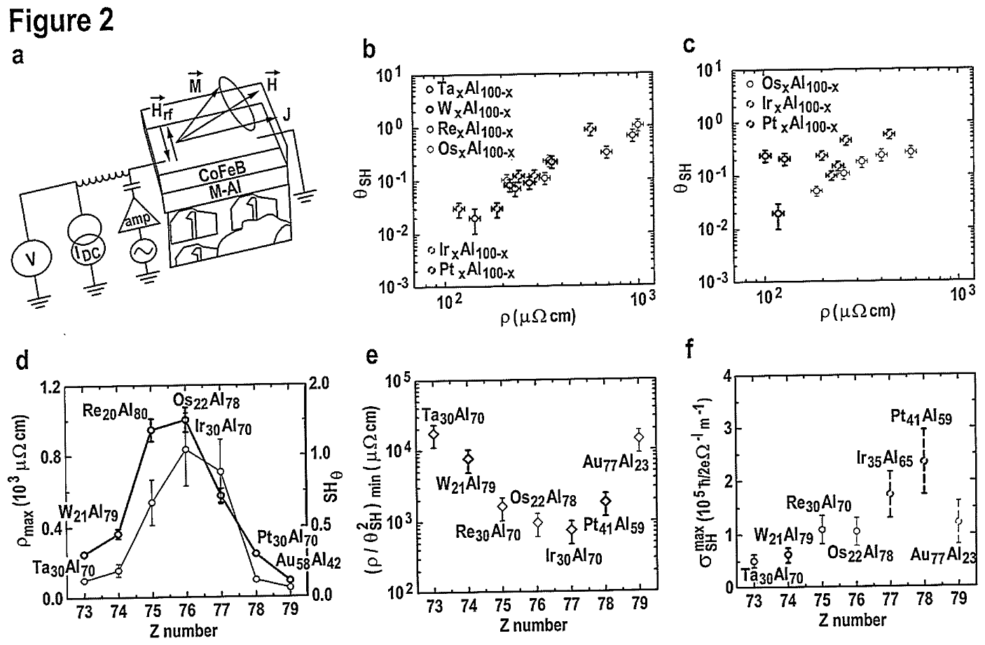

FIG. 3. Current induced domain wall motion in IrₓAl₁₀₀₋ₓ synthetic antiferromagnetic (SAF) racetracks. a) Schematic of SAF multilayer with an IrₓAl₁₀₀₋ₓ underlayer. b) Out-of-plane (red) and in-plane (blue) magnetic hysteresis loops for 43 Å Ir₅₀Al₅₀|SAFs with the out-of-plane M-H loop shown in the inset. c) Optical micrograph of the racetrack device and Kerr microscopy differential images showing the propagation of a single domain wall along the track, in response to a sequence of 5-ns-long current pulses (J˜1.2×10⁸ A cm⁻²). d) DW velocity v versus pulse current density J in nanowires formed from 43 Å IrₓAl₁₀₀₋ₓ|SAFs. e) Critical threshold current density (Jₜₕ) to drive the domain walls in IrₓAl₁₀₀₋ₓ|SAF structures, and spin Hall conductivity of IrₓAl₁₀₀₋ₓ as a function of x. f) DW velocity versus pulse current density in nanowires formed from 43 Å Ir₄₂Al₅₈ no dusting layer and dusting layer of 2 M (M=Ir and Al)|SAFs.

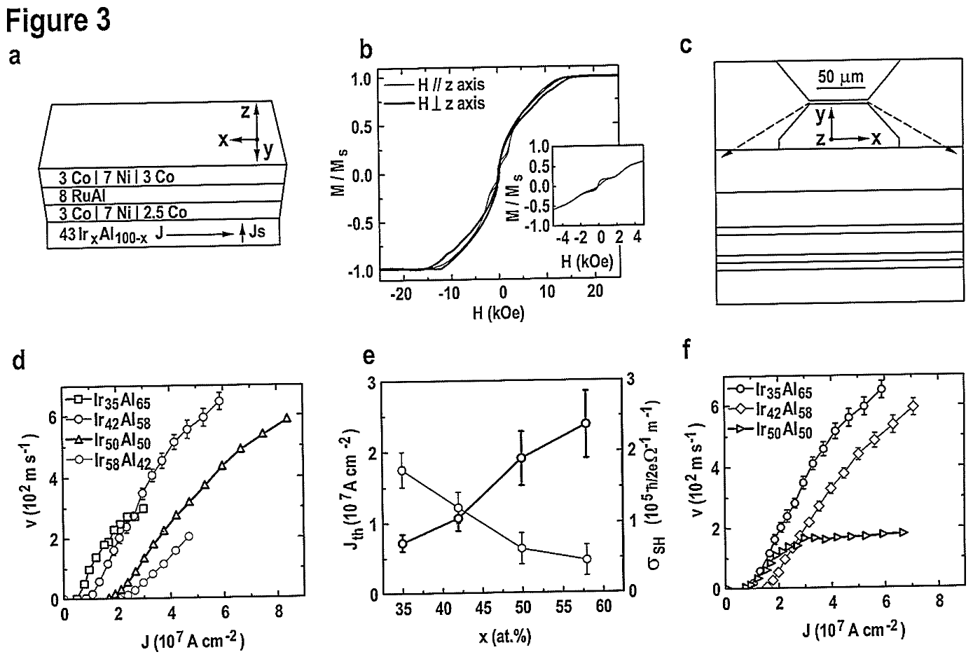

FIG. 4. Spin-orbit-torque magnetization switching. a) Schematic diagrams of sample stack and Hall bar devices. b) Anomalous Hall resistance (R_{H}) as a function of out-of-plane magnetic field H in 43 Å Ir₄₂Al₅₈|SAF structures measured at 300 K. c) Magnetization switching of 43 Å Ir₄₂Al₅₈|SAF with in-plane field of ±500 Oe at 300 K. d) Deterministic magnetization switching in 43 Å Ir₄₂Al₅₈|SAF devices by a series of ±20 V pulses. e) Anomalous Hall resistance switched by a series of positive and negative voltage pulses as a function of iteration number. f) Deterministic switching of anomalous Hall resistance.

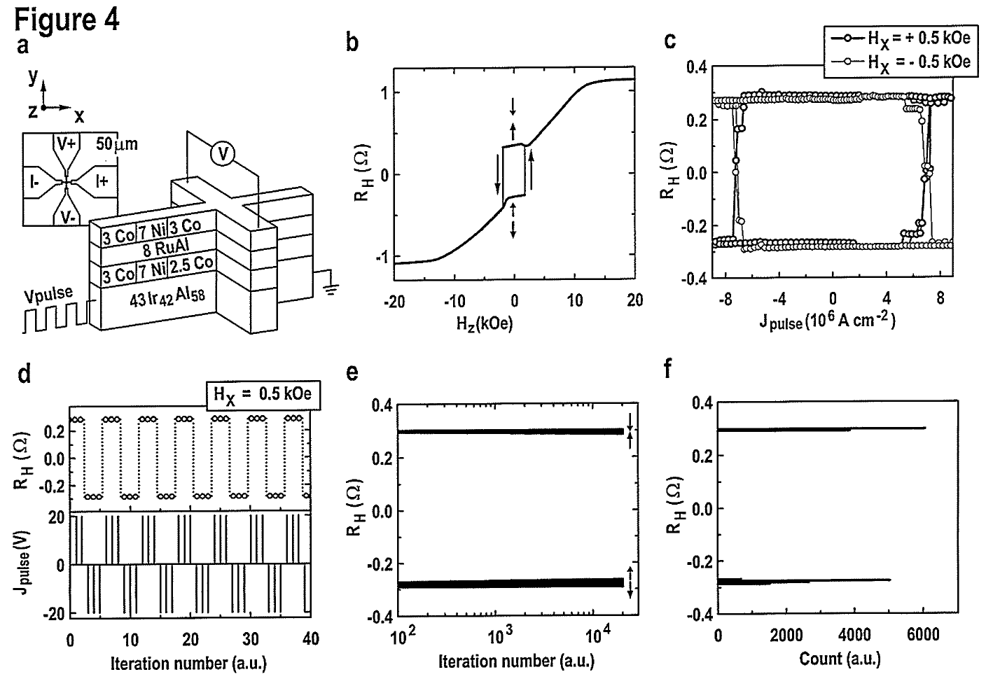

### EXPERIMENTAL SECTION

Sample Preparation, Characterization and Device Fabrication: The films were deposited in an AJA ‘Flagship Series’ sputtering system onto 10×10 mm² MgO (100) substrates. The base pressure before deposition was less than 10⁻⁸ Torr and the Ar gas pressure during deposition was 3 mTorr. The MₓAl₁₀₀₋ₓ and RuAl films were prepared by co-sputtering from heavy metal and Al targets. The Co₂₀Fe₆₀B₂₀ layer was prepared by sputtering from a single target with a composition of Co₂₀Fe₆₀B₂₀. Highly resistive 50 Å thick TaN-capping layers were fabricated by introducing 20% N₂ into the Ar sputtering gas. The composition of the MₓAl₁₀₀₋ₓ layers was determined by Rutherford backscattering spectrometry (RBS) with an accuracy of ˜1-2 atomic %. High-resolution XRD measurements were performed using a Bruker D8 Discover system with Cu Kα1 radiation (λ=1.54 Å) at room temperature. Magnetization hysteresis loops were measured using a superconducting quantum interference device vibrating sample magnetometer (SQUID-VSM). Lamella were prepared for XTEM with focused ion beam milling using a Tescan GAIA3 instrument. TEM data were measured in a FEI Titan 80-300 (scanning) TEM equipped with a CEOS CESCOR third-order axial geometric aberration corrector and a Gatan UltraScan 1000 slow-scan CCD camera. The primary electron energy was 300 kV. Device fabrication was carried out using optical lithography and ion beam etching. Subsequently, 3 nm thick Ti and 80 nm thick Au electrical contact layers were deposited using a lift-off process. The resistance of the MₓAl₁₀₀₋ₓ films was measured using a Veeco FPP5000 four-point probe station. The thickness of the MₓAl₁₀₀₋ₓ thin films was measured using a Bruker Dimensional Icon Atomic Force Microscope.

Spin-Torque Ferromagnetic Resonance: ST-FMR measurements were performed at room temperature in micro-strip devices of various sizes. A gigahertz frequency probe tip (Picoprobe Model 40A) was used to inject an RF excitation current (Keysight MXG N5183B signal generator) at a power of 20 dBm. The rectified DC voltage across the micro-strip was simultaneously measured using a bias-tee (Tektronix PSPL5545) and a nanovoltmeter (Keithley 2182A). The rectified DC voltage resulting from mixing of the RF current with the varying resistance of the micro-strip due to the anisotropic magnetoresistance of the Co₂₀Fe₆₀B₂₀ layer gives rise to the FMR signal. The FMR signal at a particular excitation frequency is measured as the external in-plane magnetic field is swept, at an angle of 45° to the long axis of the micro-strip. The D.C bias current was applied from −2 to 2 mA with an RF-current with a frequency of 9 GHz to extract the half-width of the ferromagnetic resonance peak to obtain the effective spin Hall angle.

Measurement of DW Velocity: Kerr optical microscopy in differential mode was used to monitor the position of the DW along the nanowire in response to a series of current pulses. The sensitivity of this technique is sufficient to detect the motion of single DWs in nanowires as narrow as ˜100 nm. Images are taken after a fixed number of current pulses chosen such that the DW has moved by a significant distance, typically ˜1-2 μm. The DW velocity is then determined by assuming that the DW moves only during pulses. We use a linear fit of the DW position versus the integrated current pulse length t_{CP}, that is, the product of pulse duration and the number of pulses applied. In some cases, the DW may be pinned by a local defect until enough pulses are applied to dislodge it. In these cases, we fit only the portions of the curve in which the DW position depends linearly on t_{CP}. The standard deviation of the differential velocity, that is, the point-by-point derivative of the DW position versus t_{CP} curve, is used to determine an error bar. Note that we define the DW velocity to be positive (negative) when the DWs move along the current (against) flow.

Electronic Transport Measurements: Electrical transport measurements, including (ST-FMR), Hall measurement, and electrical switching measurement, were performed at room temperature. For conventional Hall measurements, a DC current source (Keithley 6221) and a nanovoltmeter (Keithley 2182a) were used. Electrical switching experiments using ms-long current pulses were made with a multifunctional source meter (Keithley 2635B). More details are given in Supporting Information.

Statistical Analysis: 1. Pre-processing of data: σ=1/ρ, M/Mₛ (Mₛ is saturation magnetization, M is magnetization versus magnetic field). 2.

$$SD = \sqrt{\frac{{Σ ( x - \overline{x} )}^{2}}{n - 1}} , \overline{x} = \frac{( Σ x )}{n} ,$$

3. Sample size (n) is 5. 4. Two-sided testing with alpha value (0.05) and P value (0.5734). 5. Software used for statistical analysis: Origin 2019.

### REFERENCES

[1] J. Sinova, S. O. Valenzuela, J. Wunderlich, C. H. Back, T. Jungwirth, Rev. Mod. Phys. 2015, 87, 1213.
[2] A. Manchon, J. Železný, I. M. Miron, T. Jungwirth, J. Sinova, A. Thiaville, K. Garello, P. Gambardella, Rev. Mod. Phys. 2019, 91, 035004.
[3] Q. Shao, P. Li, L. Liu, H. Yang, S. Fukami, A. Razavi, H. Wu, F. Freimuth, Y. Mokrousov, M. D. Stiles, S. Emori, A. Hoffmann, J. Akerman, K. Roy, J.-P. Wang, S.-H. Yang, K. Garellob, W. Zhang, IEEE Trans. Magn. 2021, 1.
[4] S.-H. Yang, Appl. Phys. Lett. 2020, 116, 120502.
[5] S.-H. Yang, R. Naaman, Y. Paltiel, S. S. P. Parkin, Nat. Rev. Phys., 2021, 3, 328.
[6] S. Ikegawa, F. B. Mancoff, J. Janesky, S. Aggarwal, IEEE Trans. Electron Devices, 2020, 67, 1407.
[7] S. Parkin, S.-H. Yang, Memory on the racetrack. Nat. Nanotech., 2015, 10, 195.
[8] S. S. P. Parkin, M. Hayashi, L. Thomas, Science. 2008, 320, 190.
[9] Z. Chi, Y.-C. Lau, X. Xu, T. Ohkubo, K. Hono, M. Hayashi, Sci. Adv. 2020, 6, eaay2324.
[10] M. Dc, R. Grassi, J.-Y. Chen, M. Jamali, D. R. Hickey, D. Zhang, Z. Zhao, H. Li, P. Quarterman, Y. Lv, M. Li, A. Manchon, K. A. Mkhoyan, T. Low, J.-P. Wang, Nat. Mater. 2018, 17, 800.
[11] M. Mogi, K. Yasuda, R. Fujimura, R. Yoshimi, N. Ogawa, A. Tsukazaki, M. Kawamura, K. S. Takahashi, M. Kawasaki, Y. Tokura, Nat. Commun. 2021, 12, 1404.
[12] K. Kondou, R. Yoshimi, A. Tsukazaki, Y. Fukuma, J. Matsuno, K. S. Takahashi, M. Kawasaki, Y. Tokura, Y. Otani, Nat. Phys. 2016, 12, 1027.
[13] H. Wu, P. Zhang, P. Deng, Q. Lan, Q. Pan, S. A. Razavi, X. Che, L. Huang, B. Dai, K. Wong, X. Han, K. L. Wang, Phys. Rev. Lett. 2019, 123, 207205.
[14] B. Zhao, D. Khokhriakov, Y. Zhang, H. Fu, B. Karpiak, A. Md. Hoque, X. Xu, Y. Jiang, B. Yan, S. P. Dash, Phys. Rev. Research. 2020, 2, 013286.
[15] N. P. Armitage, E. J. Mele, A. Vishwanath, Rev. Mod. Phys. 2018, 90, 015001.
[16] N. Nagaosa, T. Morimoto, Y. Tokura, Nat. Rev. Mater. 2020, 5, 621.
[17] Y. Niimi, Y. Kawanishi, D. H. Wei, C. Deranlot, H. X. Yang, M. Chshiev, T. Valet, A. Fert, Y. Otani, Phys. Rev. Lett. 2012, 109, 156602.
[18] X. Shu, J. Zhou, J. Deng, W. Lin, J. Yu, L. Liu, C. Zhou, P. Yang, J. Chen, Phys. Rev. Mater. 2019, 3, 114410.
[19] Y.-C. Lau, T. Seki, K. Takanashi, APL Mater. 2021, 9, 081113.
[20] J. Han, A. Richardella, S. A. Siddiqui, J. Finley, N. Samarth, L. Liu, Phys. Rev. Lett. 2017, 119, 077702.
[21] P. Jensen, A.-L. Barabesi, H. Larralde, S. Havlin, H. E. Stanley, Chaos, Solitons & Fractals. 1995, 6, 227.
[22] P. Šmilauer, Contemp. Phys. 1991, 32, 89.
[23] L. Liu, T. Moriyama, D. C. Ralph, R. A. Buhrman, Phys. Rev. Lett. 2011, 106, 036601.
[24] W. Zhang, W. Han, X. Jiang, S.-H. Yang, S. S. P. Parkin, Nat. Phys. 2015, 11, 496.
[25] L. Liu, C.-F. Pai, Y. Li, H. W. Tseng, D. C. Ralph, R. A. Buhrman, Science. 2012, 336, 555.
[26] J. Liu, T. Ohkubo, S. Mitani, K. Hono, M. Hayashi, Appl. Phys. Lett. 2015, 107, 232408.
[27] K.-U. Demasius, T. Phung, W. Zhang, B. P. Hughes, S.-H. Yang, A. Kellock, W. Han, A. Pushp, S. S. P. Parkin, Nat. Commun. 2016, 7, 1.
[28] M.-H. Nguyen, M. Zhao, D. C. Ralph, R. A. Buhrman, Appl. Phys. Lett. 2016, 108, 242407.
[29] K.-S. Ryu, L. Thomas, S.-H. Yang, S. Parkin, Nat. Nanotech. 2013, 8, 527.
[30] K.-S. Ryu, S.-H. Yang, L. Thomas, S. S. P. Parkin, Nat. Commun. 2014, 5, 3910.
[31] S.-H. Yang, K.-S. Ryu, S. Parkin, Nat. Nanotech. 2015, 10, 221.
[32] R. Bläsing, T. Ma, S.-H. Yang, C. Garg, F. K. Dejene, A. T. N'Diaye, G. Chen, K. Liu, S. S. P. Parkin, Nat. Commun. 2018, 9, 4984.
[33] Y. Guan, X. Zhou, T. Ma, R. Bläsing, H. Deniz, S.-H. Yang, S. S. P. Parkin, Adv. Mater. 2021, 33, 2007991.
[34] F. Ajejas, V. Křižáková, D. S. Chaves, J. Vogel, P. Perna, R. Guerrero, A. Gudin, J. Camarero, S. Pizzini. Appl. Phys. Lett. 2017, 111, 202402.
[35] K. Gupta, R. J. H. Wesselink, R. Liu, Z. Yuan, P. J. Kelly. Phys. Rev. Lett. 2020, 124, 087702.
[36] T. Fache, J. C. Rojas-Sanchez, L. Badie, S. Mangin, S. Petit-Watelot Phys. Rev. B, 2020, 102, 064425.
[37] J. Bass, W. P. Pratt, J. Condens. Matter Phys. 2007, 19, 183201.
[38] P. X. Zhang, L. Y. Liao, G. Y. Shi, R. Q. Zhang, H. Q. Wu, Y. Y. Wang, F. Pan, C. Song, Phys. Rev. B. 2018, 97, 214403.

1. A Giant spin Hall effect material consisting of MₓAl₁₀₀₋ₓ, wherein M=a 5d metal selected from a 5d¹ to 5d⁹ metal and x=15-40.

2. The Giant spin Hall effect material according to claim 1, wherein x=18-35.

3. The Giant spin Hall effect material according to claim 1, wherein M=W, Re, Os or Jr.

4. The Giant spin Hall effect material according to claim 1, wherein M=Re or Os.

5. The Giant spin Hall effect material according to claim 1, wherein MₓAl₁₀₀₋ₓ is oriented along the [001] axis.

6. A racetrack memory device comprising a Giant spin Hall effect material according to claim 1.

7. The Racetrack memory device according to claim 6, wherein the racetrack has a layer sequence MₓAl₁₀₀₋ₓ|Co|Ni|Co|RuAl|Co|Ni|Co, and
wherein M=5d metal selected from Lu, Hf, Ta, W, Re, Os, Ir, or Pt, and x=15-40.

8. The Racetrack memory device according to claim 6, wherein M=W, Re, Os or Ir

9. The Racetrack memory device according to claim 6, wherein x=15-40.

10. The Racetrack memory device according to claim 6, wherein x=18-35.

11. A method of manufacturing the Giant spin Hall effect material according to claim 1, comprising depositing films of the MₓAl₁₀₀₋ₓ alloy in a sputtering system by co-sputtering 5d metal and Al targets, wherein M=5d metal selected from Lu, Hf, Ta, W, Re, Os, Ir, or Pt, and x=15-40.

12. A method of manufacturing the racetrack according to claim 6 comprising depositing films of the MₓAl₁₀₀₋ₓ alloy onto MgO (100) substrates, wherein M=5d metal selected from Lu, Hf, Ta, W, Re, Os, Ir, or Pt, and x=15-40.

13. A magnetic random-access memory (MRAM) incorporating the Giant spin Hall effect material according to claim 1.

14. The Giant spin Hall effect material according to claim 1, wherein the 5d¹ to 5d⁹ metal is selected from Lu, Hf, Ta, W, Re, Os, Ir or Pt.
